(19) United States
(12) Patent Application Publication
(10) Pub. No.: US 2015/0061019 A1
(43) Pub. Date: Mar. 5, 2015

(54) METHOD OF MANUFACTURING A SEMICONDUCTOR DEVICE

(71) Applicants: John Christopher Rudin, Bristol (GB); Charalampos Fragkiadakis, Bristol (GB)

(72) Inventors: John Christopher Rudin, Bristol (GB); Charalampos Fragkiadakis, Bristol (GB)

(21) Appl. No.: 14/389,522

(22) PCT Filed: Apr. 20, 2012
(86) PCT No.: PCT/EP2012/057312

§ 371 Date: Sep. 30, 2014

(51) Int. Cl. H01L 27/28; H01L 51/00; H01L 51/10; H01L 51/05

(52) U.S. Cl. CPC H01L 27/283; H01L 51/0541; H01L 51/0021; H01L 51/105
USPC 257/347; 438/674

(57) ABSTRACT

Embodiments of the present invention provide methods of fabricating features of a semiconductor device array, the method including patterning a dielectric layer deposited on a conductive carrier, wherein patterning comprises forming a trench pattern defining at least one device contact, electrodepositing metal into the patterned trenches, transferring the dielectric layer and the electrodeposited metal to a substrate and removing the conductive carrier, and the method further comprising lithographically fabricating one or more further features of the semiconductor device array overlying the dielectric layer and electrodeposited metal.

### BACKGROUND

Thin film transistors (TFTs) are well known in the art and are found in many applications. One common application of TFTs is in flat panel display screens such as liquid crystal displays (LCD) and organic light emitting diode (OLED) displays. Typically, each pixel in the display has an associated thin-film transistor allowing the individual elements of the display to be addressed in rows and columns.

In traditional displays, the thin-film transistors are fabricated in a layer of semiconductor material deposited onto a (typically) glass panel. The contacts of the individual devices, along with the long lines used for addressing, are generally formed from splutter coated metals, which are patterned photolithographically by means of a wet or dry etch, or by lift off.

These traditional fabrication techniques may require a vacuum environment which is expensive and difficult to implement for large area processes such as in large displays. Also, to ensure the long lines have a suitable low impedance when fabricated using sputtering techniques, the long lines must be wide which may limit the resolution and aperture of the finished product (i.e. the number of individual display elements per unit area.). Increasing the optical aperture of the array is particularly relevant to reflective displays or transparent arrays of sensors or actuators.

### BRIEF INTRODUCTION OF THE DRAWINGS

Embodiments of the present invention are further described hereinafter by way of example only with reference to the accompanying drawings, in which:

FIG. 1 illustrates a portion of a TFT based display array;

FIG. 2 illustrates an element in the TFT based display array of FIG. 1;

FIGS. 3a-e illustrates a method of fabricating a TFT according to embodiments of the invention;

FIG. 4 illustrates transfer characteristics of an example TFT device according to embodiments of the invention;

FIG. 5 illustrates a number of alternative example TFT devices according to embodiments of the invention;

FIG. 6 shows an image of a TFT device fabricated in accordance with the disclosed method; and FIG. 7 shows an image of a high aspect ratio electrodeposited line according to some embodiments of the invention.

### DETAILED DESCRIPTION OF AN EXAMPLE

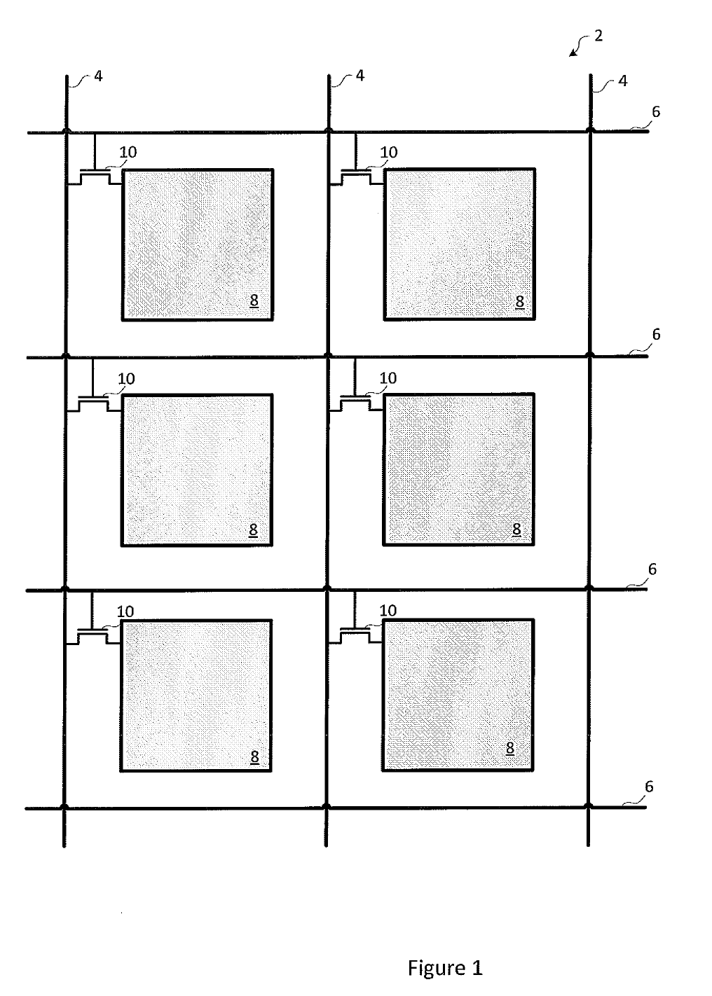

FIG. 1 illustrates a portion of a display array 2. The array 2 includes gate lines 6, data lines 4, pixel elements 8, and thin-film transistors (TFTs) 10. For each individual element in the array, a drain of a TFT 10 is coupled to a corresponding data line 4, and a gate of the TFT to a corresponding gate line 6. The source of the TFT 10 is coupled to the pixel element 8. Thus, by controlling the voltage levels on the data lines 4 and the gate lines 6, any element in the array may be individually addressed by applying a suitable voltage to the gate line and data line associated with that specific element.

For a display such as that shown in FIG. 1, the optical footprint of the TFT array (i.e. the proportion of the total display area driven by the array occluded by features of the TFT array) is typically dominated by the opaque metal long lines, i.e. the data lines 4 and gate lines 6. Thus, the optical footprint can be reduced by minimizing the width of these long lines. However, in order to ensure the lines have a suitable low line impedance, minimizing the width of the long lines requires the lines to have a high aspect ratio, for example an aspect ratio of greater than 1:2 (width:height). Traditional methods of fabricating the TFT array, including using sputter coated metals, may not be suitable for fabricating high aspect ratio lines.

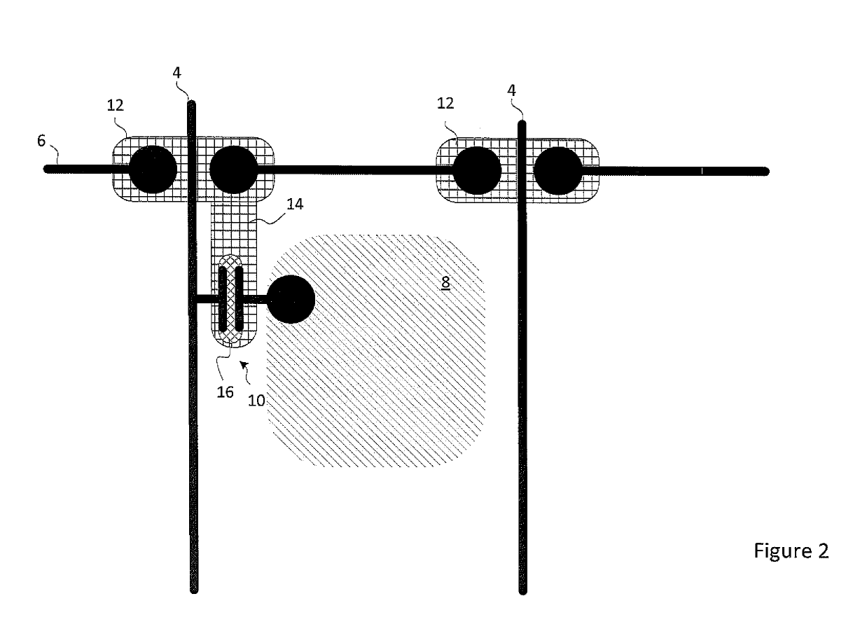

FIG. 2 illustrates an individual element in the TFT array of FIG. 1. The element includes a TFT 10 having a gate electrode 14 coupled to a gate line 6, a first source/drain contact coupled to a data line 4, and a second source/drain contact coupled to a pixel electrode 8. Gate crossovers 12 are provided where the gate line 6 crosses the data line 4. The semiconducting channel material and gate dielectric 16 are provided contacting to the source and drain contacts of the TFT 10.

Methods have been proposed to fabricate conductive elements of TFT devices using electrodeposition of metal into a pattern on a conductive carrier, once fabricated, the device can then be transferred from the conductive carrier to a substrate i.e. a pattern, plate and transfer method. The electrodepositon of metal to form contacts and to define the critical dimensions of the device has been found to provide contacts with generally good characteristics.

However, it is difficult to provide the same level of control over the process in a method of fabricating a TFT using only electrodeposition as compared to traditional lithographic techniques.

Some embodiments combine electrodeposition of device contacts to define the critical dimensions of the device, with more traditional lithographic techniques to form a gate dielectric and/or channel of a semiconductor device in order to provide the advantages of both fabrication techniques.

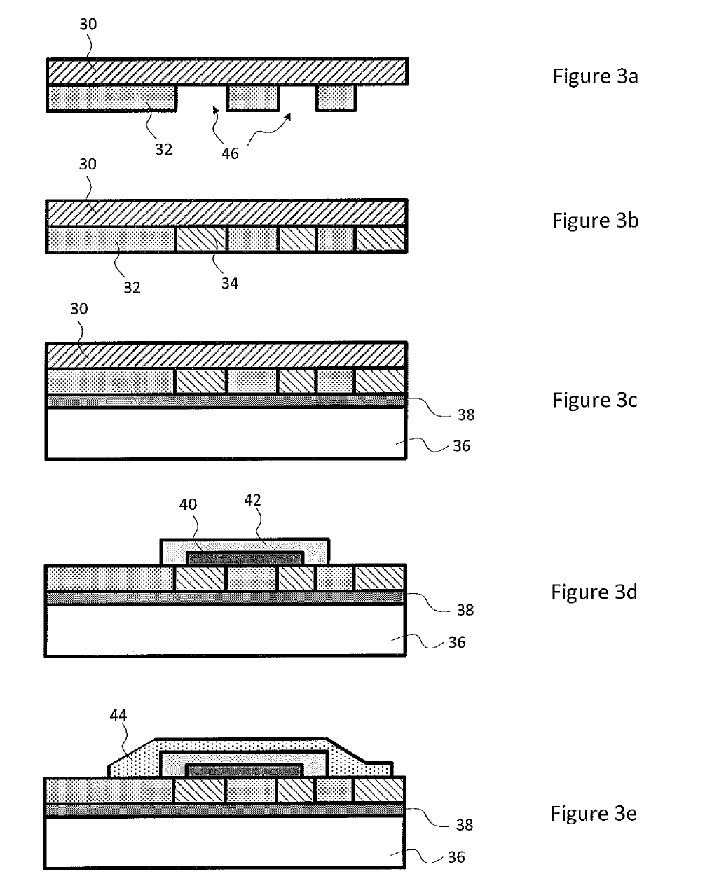

FIGS. 3a-e illustrate an example process for fabricating a thin-film transistor according to embodiments of the invention. In FIG. 3a, a conductive carrier 30 is taken and a dielectric pattern 32 is formed on the surface of the conductive layer 30. The pattern may be formed, for example, by photolithography, imprinting, or other means. The dielectric pattern includes a trench pattern 46 defining the source and drain contacts of a TFT.

In FIG. 3b, metal is electrodeposited into the trenches 46 to form metallic features 34 of the TFT device such as the source/drain contacts. Metals such as Au, Ni, Cu, Ag, Pd, etc. are typically used and can be deposited rapidly and with near bulk density and conductivity. The electrodeposition of metal may proceed in stages with different metals being deposited such that the first, and/or last, metals to be deposited are preferably those with low surface potentials to allow good current injection into a semiconductor channel of the TFT.

Once the metal has been deposited, the pattern, including the dielectric and metal, can be transferred to a final substrate 36, as shown in FIG. 3c. A layer of adhesive 38 may be applied between the pattern and the final substrate 36 to provide good adherence and the conductive carrier layer 30 may then be removed, leaving behind the dielectric 32 and metal 34 on the surface of the final substrate. The final substrate 36 may be comprised of any of a range of materials, which may not be suitable for traditional TFT fabrication processes in which the dielectric and metal are formed directly onto the substrate. For example, the described method may be particularly appropriate for fabrication of TFT arrays onto plastic or fibre based substrates.

In FIG. 3d, after the conductive carrier 30 has been removed, a layer of semiconductor 40 is applied to the surface of the transferred dielectric and metal. The layer of semiconductor may be applied by any suitable lithographic coating method, for example spin coating, gravure, slot-die, inkjet or flexography. A gate dielectric 42 is then formed overlying the semiconductor layer 40. The semiconductor layer 40 and the gate dielectric 42 may be patterned using photolithography or other lithographic techniques, such as printing patterning techniques, in order to eliminate the presence of any excess materials which may incur parasitic leakages.

In FIG. 3e, a gate 44 is then formed, for example by deposition of metal and patterning, by deposition of conductive polymer, or using conductive inks, such that contacts are made to the gate long lines 6. Suitable dielectrics may be additionally provided to provide a crossover for contact to the long lines. The resulting TFT structure can be seen in FIG. 3e.

In an alternative example, the dielectric 32 and metal 34 are not transferred from the conductive carrier 30 to the final substrate 36 prior to fabrication of the semiconductor layer 40, the gate dielectric 42, and the gate 44. Rather, the semiconductor layer 40 and gate structure is formed with the dielectric 32 and metal 34 on conductive carrier 30, and then the finished TFT device can be transferred to the final substrate 36. In this alternative example, the semiconductor layer 40, the gate dielectric 42, and the gate electrode 44 may be embedded in the adhesive layer 38 once the device is transferred to the final substrate 36 to provide extra protection to these structures.

Thus, the disclosed method provides a hybrid fabrication technique that combines electrodeposition of metallic features with more conventional deposition and lithographic fabrication of the remaining features of the semiconductor device. The planar nature of the transferred device contacts in some embodiments may be particularly advantageous for the subsequent deposition of semiconductor.

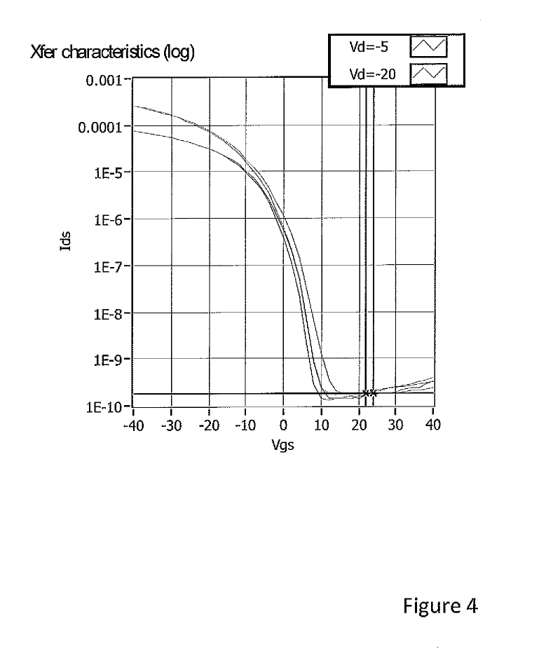

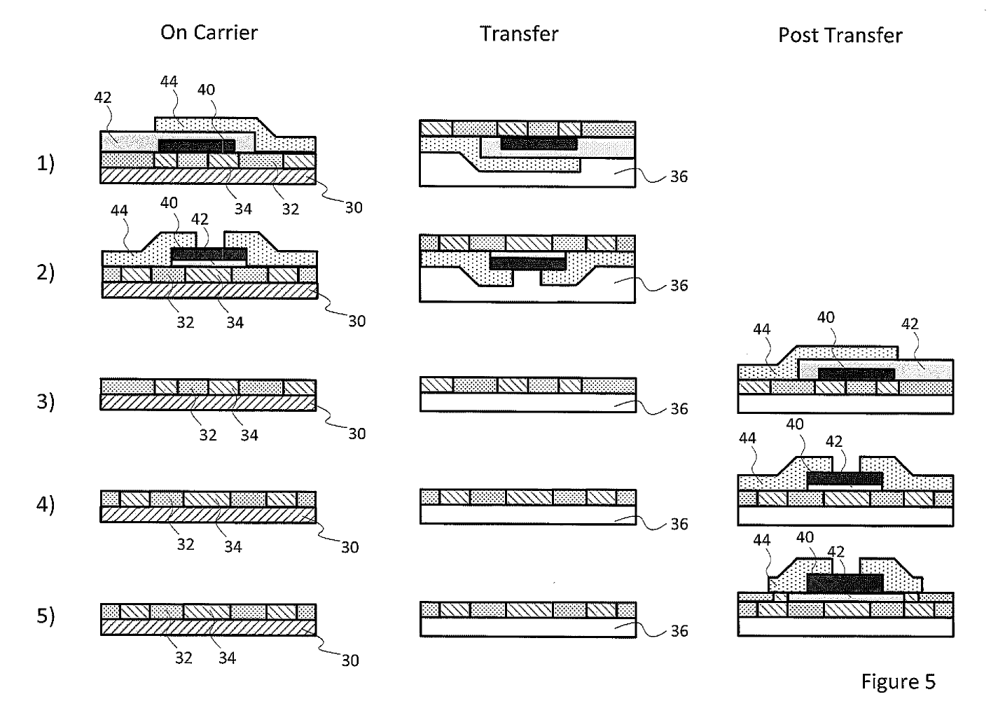

The method discussed above with reference to FIG. 3 was used to fabricate an example device having Au/Ni/Au electrodes and a small molecule organic semiconductor deposited from solution. The source/drain contacts were pre-treated with a self-assembled monolayer coupling agent . The final device produced was tested and the mobility in the linear operating region was measured to be 0.8 cm²/Vs. FIG. 4 shows the transfer function of the example device indicating ohmic contacts to the source/drain electrodes and low hysteresis for the device.

FIG. 5 illustrates a number of alternative methods of fabricating TFTs in a TFT array in accordance with embodiments of the invention. In example method 1) illustrated in FIG. 5, a top gate structure is lithographically fabricated on top of the patterned dielectric 32 and electrodeposited metal 34 on the conductive carrier 30 prior to transfer to the final substrate 36. In example method 2), a bottom gate structure is lithographically fabricated on top of the patterned dielectric 32 and electrodeposited metal 34.

For each of the example methods 1)-2), the devices are fabricated pre-transfer and are effectively encapsulated in an adhesive layer during the transfer step. Furthermore, for a TFT array fabricated according to these methods, the finished TFT array has a planarised surface ready for any subsequent processing steps.

Three further example methods, 3)-5) are illustrated in FIG. 5. In each of these methods, a patterned dielectric and electrodeposited metal forming source/drain contacts as well as the long lines of the TFT array are transferred to the final substrate 36 prior to the lithographic fabrication of a channel, gate dielectric and other conductors. Example 3) is similar to the method described in FIGS. 3a-3e.

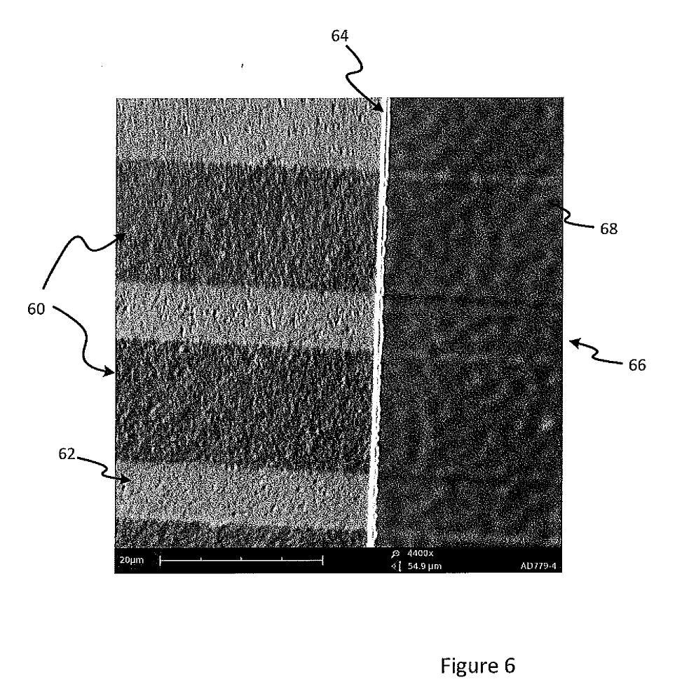

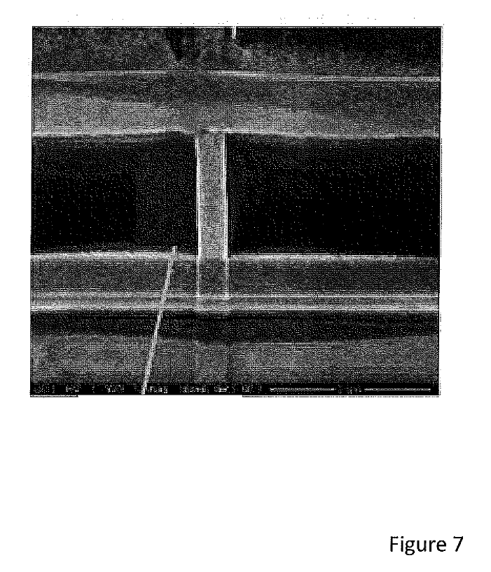

FIG. 6 shows a scanning electron microscope image of a device fabricated according to the above described method. Transferred source and drain regions 60 can be seen deposited between regions of dielectric 62. On the right of the image, features overlying the transferred metal and dielectric are visible including channel region 66 and gate electrode 68, while the edge of the lithographically formed semiconductor and dielectric can be seen 64.

It has been found that in devices fabricated using electrodeposited metal, the metal generally contains artifacts of the electrolytic process by which they were formed.

Furthermore, in order to fabricate the long lines in a semiconductor device array it is proposed to extend the pattern, electrodeposit and transfer method, in which a pattern is formed on a conductive carrier defining regions in which metal is to be deposited, and then metal is electrodeposited into the pattern, to form the long lines as well as device contacts for individual semiconductor devices in the array. The pattern and electrodeposited metal can then be transferred from the carrier to a substrate. By using this method, long lines can be fabricated with high throughput, high resolution, high aspect ratio and low line impedance along with device contacts in the same patterning and deposition steps.

FIG. 7 is an image of a long line fabricated using the pattern, electrodeposit , and transfer method. As can be seen from FIG. 7, the fabricated line has a high aspect ratio with dimensions of approximately 0.3 μm wide and 2 μm in depth.

It has been demonstrated that using this pattern, electrodeposit and transfer method, an electrodeposited long line pattern can be transferred to a substrate onto which a TFT array can be fabricated. However, some difficulties may be encountered with correct alignment of the lithography of the individual thin-film transistors and with the critical dimensions of each TFT with the long lines.

According to some described embodiments, the long lines, i.e. the gate lines 6 and data lines 4, as well as the critical dimensions of the TFT are fabricated using a single patterning step in which a trench pattern defining both the long lines and device contacts is formed in a dielectric layer on a conductive plate. Metal is then electrodeposited into the trench pattern. The use of a single patterning step, followed by electrodeposition of the metal may lead to reduced costs and complexity and increased production yield for the fabrication method.

In particular, methods of fabricating semiconductor device arrays are disclosed that use electroformed metals for the source and drain contacts as well as the long lines of the array, which are formed and may be transferred from a conductive carrier to a final substrate prior to the semiconductor being deposited and a traditional top gate formed by metal or conductive polymer deposition.

The extended pattern, electrodesposit and transfer method described above, can be combined with the hybrid fabrication method described in conjunction with FIG. 3, such that long lines and device contacts of a semiconductor device array, such as a TFT array, can be electrodeposited into a patterned dielectric layer, and then features of each semiconductor device in the array can be fabricated using traditional lithographic techniques overlying the electrodeposited metal and dielectric layer. As shown with the examples in FIG. 5 the lithographic fabrication of features of the semiconductor devices can be performed pre or post transfer of the electrodeposited metal and dielectric layer to the substrate.

The disclosed technique provides a method of fabricating the long lines (gate and data lines) and the critical device dimensions (channel length and width) using the same patterning step and without the requirement for long scale pattern alignment, or small scale tight tolerances. While the disclosed methods may be used in conjunction with a range of different substrate materials, including traditional materials such as glass, the removal of the requirement for long scale pattern alignment, or small scale tight tolerances may make the disclosed methods particularly applicable to the processing of plastic substrates.

The use of electrodeposition for fabricating the contacts and long lines may allow the required amounts of precious metals (e.g. Au, Ag, Pd, etc.) commonly used for contact metallization to be minimized, as this is an additive process. Electro-deposited base metals such as Nickel or Copper can also be finished with suitable contact metals such as Au or Pd by means of electroless deposition prior to the deposition of the semiconductor.

The disclosed techniques can be further extended to provide for the fabrication of crossovers between the gate and data lines using electrodeposition of metal to form the crossover structure. This can be achieved by providing an insulating layer overlying a first long line at the location of a crossover and then electrodepositing metal overlying the insulating layer to couple two separate portions of a second long line to provide the crossover.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

1. A method of fabricating features of a semiconductor device, the method comprising:
patterning a dielectric layer deposited on a conductive carrier, wherein patterning comprises forming a trench pattern defining at least one device contact; electrodepositing metal into the patterned trenches;
transferring the dielectric layer and the electrodeposited metal to a substrate and removing the conductive carrier; and the method further comprising:
lithographically fabricating one or more further features of the semiconductor device overlying the dielectric layer and electrodeposited metal.

2. The method of claim 1, comprising lithographically fabricating the one or more further features prior to and/or subsequent to transferring the dielectric later and the electrodeposited metal to the substrate.

3. The method of claim 1 further comprising providing an adhesive layer between the substrate and the transferred dielectric layer and electrodeposited metal.

4. The method of claim 1, wherein patterning the dielectric layer further comprises photolithographically patterning the dielectric layer.

5. The method of claim 1, wherein the patterning the dielectric layer further comprises imprinting a pattern into the dielectric layer.

6. The method of claim 1, wherein the semiconductor device forms part of a semiconductor device array.

7. The method of claim 6, wherein patterning a dielectric layer further comprises forming a trench pattern defining at least one long line of the semiconductor device array, and wherein electrodepositing metal into the patterned trenches includes electrodepositing metal into the trench pattern defining at least one long line.

8. The method of claim 7, wherein the at least one long line comprises a gate line and/or a data line of the semiconductor device array.

9. The method of claim 7, wherein the semiconductor device array comprises a TFT array.

10. A semiconductor device comprising:
at least one device contact component comprising metal electrodeposited into a pattern in a dielectric layer; and
one or more further features lithographically fabricated overlying the dielectric layer and electrodeposited metal.

11. A semiconductor device array comprising the semiconductor device of claim 10, the semiconductor device array further comprising at least one long line comprising metal electrodeposited into the pattern in the dielectric layer.

12. The semiconductor device array of claim 11, wherein the long line comprises at least one of a data line and a gate line.

13. The semiconductor device array of claim 10, wherein the semiconductor device array comprises a TFT array.

14. The semiconductor device array of claim 10, wherein the electrodeposited metal comprises at least one of: gold, nickel, copper, silver, or palladium.

15. A method of fabricating features of a semiconductor device array, the method comprising:
patterning a dielectric layer deposited on a conductive carrier, wherein patterning comprises forming a trench pattern defining at least one device contact and a long line of the semiconductor device array; and
electrodepositing metal into the patterned trenches.
